(19) United States
(12) Patent Application Publication
(10) Pub. No.: US 2024/0040778 A1
(43) Pub. Date: Feb. 1, 2024

(54) MEMORY STRUCTURE, SEMICONDUCTOR STRUCTURE AND METHOD FOR MANUFACTURING SAME

(71) Applicant: CHANGXIN MEMORY TECHNOLOGIES, INC., Hefei City (CN)

(72) Inventor: Xiang LIU, Hefei City (CN)

(73) Assignee: CHANGXIN MEMORY TECHNOLOGIES, INC., Hefei City (CN)

(21) Appl. No.: 18/451,565

(22) Filed: Aug. 17, 2023

Related U.S. Application Data
(63) Continuation of application No. PCT/CN2022/111619, filed on Aug. 11, 2022.

(30) Foreign Application Priority Data
Aug. 1, 2022 (CN) 202210915944.6

(51) Int. Cl. H10B 12/00; H01L 21/762

(52) U.S. Cl. CPC H10B 12/488; H10B 12/02; H01L 21/76229

(57) ABSTRACT

A semiconductor structure includes a substrate and word line structures. An isolation structure is formed in the substrate, and the isolation structure defines active areas in the substrate. The isolation structure includes a trench formed in the substrate, an isolation layer filled in the trench, and a shielding layer located in the isolation layer. The word line structures are located in the substrate, pass through the isolation structure and the active areas, and are located above the shielding layer.

### CROSS-REFERENCE TO RELATED APPLICATIONS

This is a continuation of International Patent Application No. PCT/CN2022/111619 filed on Aug. 11, 2022, which claims priority to Chinese Patent Application No. 202210915944.6 filed on Aug. 1, 2022. The disclosures of the above-referenced applications are hereby incorporated by reference in their entirety.

### BACKGROUND

Dynamic random access memory (DRAM) is a kind of semiconductor memory, the greatest advantage of which lies in its small layout area.

Due to the increasing reduction of the feature dimension of a DRAM device, the distance between word lines (WL) becomes increasingly smaller. The switching of word lines will cause leakage, which will affect other nearby memory cells. If a same WL address is continuously accessed for a long time, it will even lead to the loss of the information of the memory cells near the WL, thereby leading to a reduction of product yields.

### SUMMARY

According to embodiments of the disclosure, a memory structure, a semiconductor structure and a method for manufacturing the same are provided.

According to some embodiments, one aspect of the disclosure provides a semiconductor structure, including a substrate and word line structures. An isolation structure is formed in the substrate, and the isolation structure defines active areas in the substrate. The isolation structure includes a trench formed in the substrate, an isolation layer filled the trench, and a shielding layer located in the isolation layer. The word line structures are located in the substrate, pass through the isolation structure and the active areas and are located above the shielding layer.

According to some embodiments, another aspect of the embodiments of the disclosure also provides a method for manufacturing a semiconductor structure, including the following operations.

A substrate is provided.

An isolation structure is formed in the substrate. The isolation structure defines active areas in the substrate. The isolation structure includes a trench formed in the substrate, an isolation layer filled in the trench, and a shielding layer located in the isolation layer.

Word line structures are formed in the substrate. The word line structures pass through the isolation structure and the active areas and are located above the shielding layer.

According to some embodiments, yet another aspect of the embodiments of the disclosure further provides a memory structure including the semiconductor structure provided by any of the above embodiments.

Details of one or more embodiments of the disclosure are set forth in the following accompany drawings and description. Other features, objects and advantages of the present disclosure will become apparent from the accompany drawings, the specification and the claims.

### BRIEF DESCRIPTION OF THE DRAWINGS

In order to more clearly illustrate the technical solutions of the embodiments of the disclosure, a brief description of the accompanying drawings used in the embodiments will be provided below. Apparently, the drawings of the following description are merely some embodiments of the disclosure. For a person of ordinary skill in the art, other drawings can be obtained based on these drawings without creative work.

FIG. 1 is a flowchart of a method for manufacturing a semiconductor structure provided by one embodiment of the disclosure.

FIG. 2 is a flowchart of operation S300 in a method for manufacturing a semiconductor structure provided by one embodiment of the disclosure.

FIG. 3 is a flowchart of operation S200 in a method for manufacturing a semiconductor structure provided by one embodiment of the disclosure.

FIG. 4A is a perspective view of a structure obtained in operation S100 of a method for manufacturing a semiconductor structure provided by one embodiment of the disclosure.

FIG. 4B is a cross-sectional view of the structure obtained in operation S100 of a method for manufacturing a semiconductor structure provided by one embodiment of the disclosure

FIG. 4C is a top view of the structure obtained in operation S100 of a method for manufacturing a semiconductor structure provided by one embodiment of the disclosure.

FIG. 5A is a perspective view of a structure obtained in operation S220 of a method for manufacturing a semiconductor structure provided by one embodiment of the disclosure.

FIG. 5B is a cross-sectional view of the structure obtained in operation S220 of a method for manufacturing a semiconductor structure provided by one embodiment of the disclosure.

FIG. 5C is a top view of the structure obtained in operation S220 of a method for manufacturing a semiconductor structure provided by one embodiment of the disclosure.

FIG. 6A is a perspective view of a structure obtained in operation S230 of a method for manufacturing a semiconductor structure provided by one embodiment of the disclosure.

FIG. 6B is a cross-sectional view of the structure obtained in operation S230 of a method for manufacturing a semiconductor structure provided by one embodiment of the disclosure.

FIG. 6C is a top view of the structure obtained in operation S230 of a method for manufacturing a semiconductor structure provided by one embodiment of the disclosure.

FIG. 7A is a perspective view of a structure obtained in operation S230 of a method for manufacturing a semiconductor structure provided by one embodiment of the disclosure.

FIG. 7B is a cross-sectional view of the structure obtained in operation S230 of a method for manufacturing a semiconductor structure provided by one embodiment of the disclosure.

FIG. 7C is a top view of the structure obtained in operation S230 of a method for manufacturing a semiconductor structure provided by one embodiment of the disclosure.

FIG. 8A is a perspective view of a structure obtained in operation S240 of a method for manufacturing a semiconductor structure provided by one embodiment of the disclosure.

FIG. 8B is a cross-sectional view of the structure obtained in operation S240 of a method for manufacturing a semiconductor structure provided by one embodiment of the disclosure.

FIG. 8C is a top view of the structure obtained in operation S240 of a method for manufacturing a semiconductor structure provided by one embodiment of the disclosure.

FIG. 9A is a perspective view of a structure obtained in operation S240 of a method for manufacturing a semiconductor structure provided by one embodiment of the disclosure.

FIG. 9B is a cross-sectional view of the structure obtained in operation S240 of a method for manufacturing a semiconductor structure provided by one embodiment of the disclosure.

FIG. 9C is a top view of the structure obtained in operation S240 of a method for manufacturing a semiconductor structure provided by one embodiment of the disclosure.

FIG. 10A is a perspective view of a structure obtained after a third isolation dielectric material layer is formed in a method for manufacturing a semiconductor structure provided by one embodiment of the disclosure.

FIG. 10B is a cross-sectional view of the structure obtained after the third isolation dielectric material layer is formed in a method for manufacturing a semiconductor structure provided by one embodiment of the disclosure.

FIG. 10C is a top view of the structure obtained after the third isolation dielectric material layer is formed in a method for manufacturing a semiconductor structure provided by one embodiment of the disclosure.

FIG. 11A is a perspective view of a structure obtained in operation S300 of a method for manufacturing a semiconductor structure provided by one embodiment of the disclosure. FIG. 11A is also a perspective view of a semiconductor structure provided by one embodiment of the disclosure.

FIG. 11B is a cross-sectional view of the structure obtained in operation S300 of a method for manufacturing a semiconductor structure provided by one embodiment of the disclosure. FIG. 11B is also a cross-sectional view of the semiconductor structure provided by one embodiment of the disclosure.

FIG. 11C is a top view of the structure obtained in operation S300 of a method for manufacturing a semiconductor structure provided by one embodiment of the disclosure. FIG. 11C is also a top view of the semiconductor structure provided by one embodiment of the disclosure.

FIG. 12 is a cross-sectional view of a semiconductor structure provided by another embodiment of the disclosure.

### DETAILED DESCRIPTION

The disclosure relates to the technical field of manufacturing semiconductors, in particular to a memory structure, a semiconductor structure and a method for manufacturing the same.

In order to facilitate the understanding of embodiments of the disclosure, a more complete description will be given below with reference to the relevant drawings. The preferred embodiment of the disclosure is given in the attached drawings. However, the disclosure may be implemented in many different forms and is not limited to the embodiments described herein. Rather, these embodiments are provided to make the disclosure more thorough and comprehensive.

Unless otherwise defined, all technical and scientific terms used herein have the same meanings as those commonly understood by those skilled in the art of the disclosure. Terms used herein in the specification of the disclosure are for the purpose of describing specific embodiments only, and are not intended to limit the disclosure.

It should be understood that when an element or layer is referred to as “on”, “being electrically connected with” another element or layer, it may be directly above or electrically connected with the other element or layer, or may exist intervening elements or layers. It should be understood that, although the terms first, second, third etc. may be used to describe various elements, components, regions, layers, doping types and/or portions, the elements, components, regions, layers, doping types and/or portions should not be limited by such terms. These terms are used only to distinguish one element, component, region, layer, doping type or portion from another element, component, region, layer, doping type or portion. Accordingly, a first element, component, region, layer, doping type, or portion discussed below may be represented as a second element, component, region, layer, or portion without departing from the teachings of the present disclosure. For example, a first isolation dielectric layer may be referred to as a second isolation dielectric layer, and similarly the second isolation dielectric layer may be referred to as the first isolation dielectric layer. The first isolation dielectric layer and the second isolation dielectric layer are different isolation dielectric layers.

Spatially relational terms such as “below”, “above” may be used herein for describing a relationship between one element or feature and another element or feature illustrated in the figures. It should be understood that, the spatial relationship terms also include different orientations of devices in use and operation, in addition to the orientations shown in the figures. For example, if a device in the figures is flipped, then the element or feature described as “below” another element or feature will be oriented “above” the another element or feature. Therefore, the exemplary term “below” may include both upper and lower orientations. Moreover, the device may be additionally oriented (rotated 90 degrees or otherwise) and the spatial descriptors used herein are interpreted accordingly.

As used herein, the singular forms of “a”, “an” and “said/the” also include the plural forms, unless the context clearly indicates otherwise. It should also be understood that when the terms “compose” and/or “include” are used in this specification, the terms determine the presence of said features, integers, steps, operations, elements and/or components, but do not exclude the presence or addition of one or more other features, integers, steps, operations, elements, components and/or groups. As used herein, the term “and/or” includes any and all combinations of related listed items.

The embodiments of the disclosure are described herein with reference to cross-sectional views of schematic diagrams of ideal embodiments (and intermediate structures) in the present disclosure, so that variations in the shapes shown due to, for example, manufacturing techniques and/or tolerances can be anticipated. Accordingly, the embodiments of the present disclosure should not be limited to the specific shapes of the regions shown herein, but include shape deviations due to, for example, manufacturing techniques. The regions shown in the figures are schematic in nature and their shapes do not represent the actual shapes of the regions of the device, and do not limit the scope of the present disclosure.

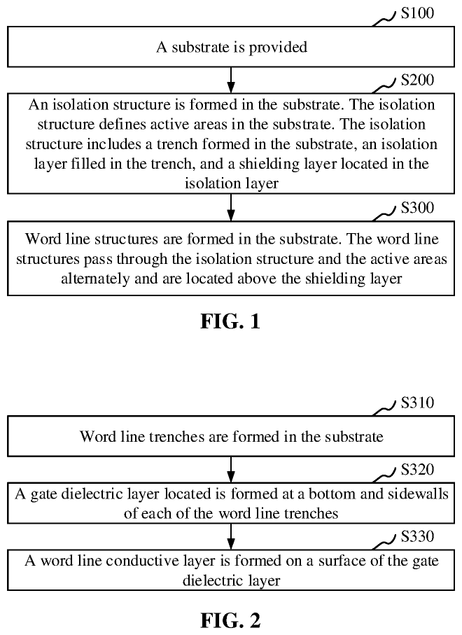

Reference is made to FIG. 1 to FIG. 12. It is to be noted that, the figures provided by this embodiment only illustrate basic ideas of the disclosure in a schematic way. Only units relating to the disclosure are shown in the figures, and the units are not drawn according to the number, shape and size of units in actual implementation. The type, number and proportion of each unit in actual implementation may be arbitrarily changed, and layout patterns of the units may be more complex.

With the high integration of semiconductors, more and more advanced processes are applied to a process for manufacturing the semiconductors, so arrangement of active areas is required to be denser. In some semiconductor structures, a staggered arrangement of active areas makes a layout of memory cells close to the densest packing. However, such a staggered arrangement layout of the active areas causes a word line to periodically pass through areas between two adjacent active areas in a set direction. In the set direction (i.e., an extending direction of the word line), the word line periodically passes through the areas between two adjacent active areas. The word line passing through the areas between two adjacent active areas is called a passing WL (PWL).

Due to the increasing reduction of the feature dimension of a DRAM device, the distance between word lines becomes increasingly smaller. When a PWL is turned on, the PWL will adsorb electrons along shallow a trench isolation structure and a surface of a substrate, forming a leakage path from a bit line contact (BLC) to a bottom of the PWL and then to a node contact (NC). Therefore, when a word line is turned on, it will not only affect the active areas through which it passes, but also cause leakage and affect other nearby memory cells. When a WL address is continuously accessed for a long time, it will even lead to a loss of the information of the memory cells near the WL, thereby leading to a reduction of product yields.

In view of this, some embodiments of the disclosure provide a method for manufacturing a semiconductor structure.

Referring to FIG. 1, according to some embodiments, the method for manufacturing a semiconductor structure includes the following operations.

In S100, a substrate is provided.

In S200, an isolation structure is formed in the substrate. The isolation structure defines active areas in the substrate. The isolation structure includes a trench formed in the substrate, an isolation layer filled in the trench, and a shielding layer located in the isolation layer.

In S300, word line structures are formed in the substrate. The word line structures pass through the isolation structure and the active areas and are located above the shielding layer.

In the method for manufacturing the semiconductor structure provided by the above embodiments, a shielding layer that is floating is formed at bottoms of the word line structures. The shielding layer can shield an electric field formed at the bottom of the word line structure, reduce the number of electrons adsorbed at the bottom of the word line structure, and inhibit formation of leakage paths, thereby alleviating leakage caused by a switching process of the word line structure and avoiding a reduction of product yields.

It is to be noted that, in the embodiments of the disclosure, active areas of a staggered arrangement are formed in the substrate. Due to the staggered arrangement of the active areas, the word line structures pass through the isolation structure and the active areas along an extension direction of the word line structures, so the word line structure will periodically pass through areas between two adjacent active areas. In the embodiments of the disclosure, the word line, when passing through areas between two adjacent active areas, is called a passing word line. In the embodiments of the disclosure, the shielding layer is located in the isolation layer, and the shielding layer thus is located in the isolation structure. Therefore, when the word line structure passes through the isolation structure and the active areas, the shielding layer shields an electric field formed at a bottom of the word line structure passing through the isolation structure (i.e., a passing word line passing through an area between two adjacent active areas. Meanwhile, the shielding layer has little influence on a potential near the word line structure passing through the active areas (also called a main word line, main WL), so it has little influence on the performance of the obtained device itself

Referring to FIG. 2, according to some embodiments, the forming word line structures in the substrate in S300 may include the following operations.

In S310, word line trenches are formed in the substrate.

In S320, a gate dielectric layer is formed at a bottom and sidewalls of each of the word line trenches.

In S330, a word line conductive layer is formed on a surface of the gate dielectric layer.

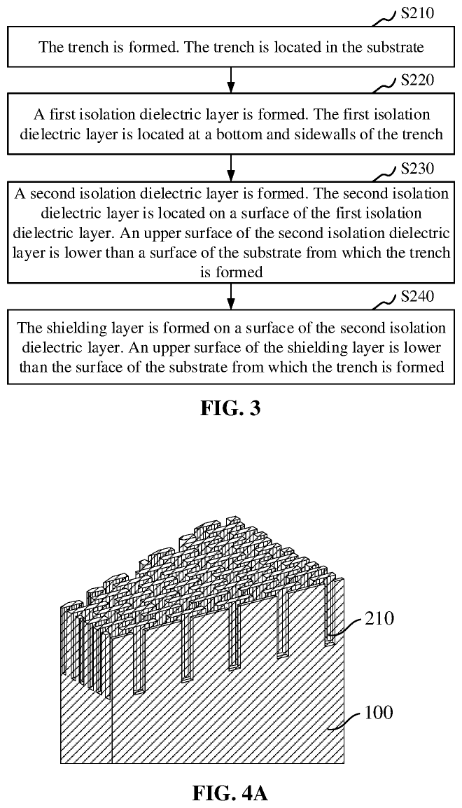

Referring to FIG. 3, according to some embodiments, the forming an isolation structure in the substrate in S200 may include the following operations.

In S210, the trench is formed in the substrate.

In S220, a first isolation dielectric layer is formed at a bottom and sidewalls of the trench.

In S230, a second isolation dielectric layer is formed on a surface of the first isolation dielectric layer. An upper surface of the second isolation dielectric layer is lower than a surface of the substrate from which the trench is formed.

In S240, a shielding layer is formed on a surface of the second isolation dielectric layer. An upper surface of the shielding layer is lower than the surface of the substrate from which the trench is formed.

According to some embodiments, the forming a first isolation dielectric layer in S220 includes the following operation.

A first isolation dielectric material layer is formed. The first isolation dielectric material layer is located at a bottom and sidewalls of the trench and covers an upper surface of the substrate.

The forming a second isolation dielectric layer in S230 includes the following operation.

A second isolation dielectric material layer is formed. The second isolation dielectric material layer fills the trench and covers a surface of the first isolation dielectric material layer. The second isolation dielectric material layer located outside the trench is removed, and the second isolation dielectric material layer located inside the trench is etched back to obtain the second isolation dielectric layer.

The forming a shielding layer on a surface of the second isolation dielectric layer in S240 includes the following operations.

A shielding material layer is formed. The shielding material layer fills the trench and covers an exposed upper surface of the first isolation dielectric material layer. The shielding material layer located outside the trench is removed, and the shielding material layer located inside the trench is etched back to form the shielding layer.

During forming the word line structures, the forming a first isolation dielectric layer in S220 may further include the following operation.

The first isolation dielectric material layer covering the upper surface of the substrate is removed to form the first isolation dielectric layer.

According to some embodiments, after the forming a shielding layer on a surface of the second isolation dielectric layer in S240, the method may further include the following operations.

A third isolation dielectric material layer is formed. The third isolation dielectric material layer fills the trench and covers the exposed upper surface of the first isolation dielectric material layer.

The third isolation dielectric material layer located outside the trench is removed, and part of the third layer of isolation dielectric material in the trench in its height direction is removed during forming the word line trenches, to form the third isolation dielectric layer located between the shielding layer and the word line trenches.

According to some embodiments, an upper surface of the word line conductive layer is lower than a top surface of the word line trench.

The forming word line structures in the substrate in S300, after forming a word line conductive layer in S330, may further include the following operation.

A filling dielectric layer is formed. The filling dielectric layer is located on the corresponding word line conductive layer and fills the corresponding word line trench.

According to some embodiments, after the forming word line structures in the substrate in S300, the method may further include the following operation.

A source and a drain are formed in each of the active areas. The source and the drain are located at two opposite sides of the corresponding one of the word line structures.

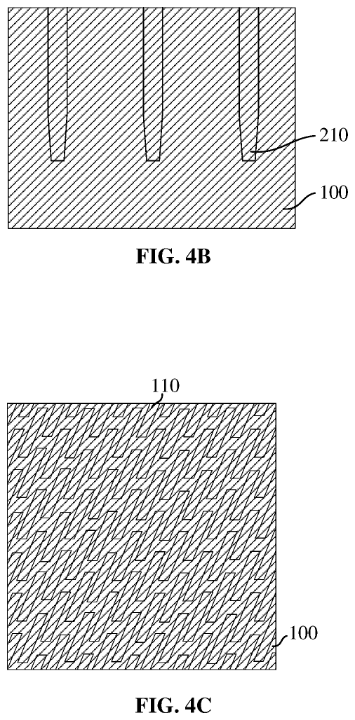

In order to explain more clearly the manufacturing method in some of the above embodiments, some embodiments provided by the disclosure will be described further below with reference to FIG. 4A to FIG. 11C.

Referring to FIG. 4A, FIG. 4B, and FIG. 4C, in S100, a substrate 100 is provided.

In the embodiments of the disclosure, a material of the substrate 100 is not specifically limited. For example, the substrate 100 may include, but is not limited to, at least one of silicon (Si) substrate, silicon carbide (SiC) substrate, gallium nitride (GaN) substrate, gallium arsenide (GaAs) substrate, sapphire substrate, glass substrate, or the like.

According to some embodiments, the substrate 100 includes silicon substrate.

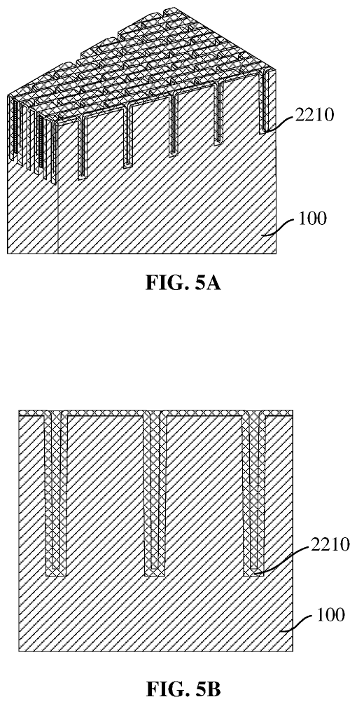

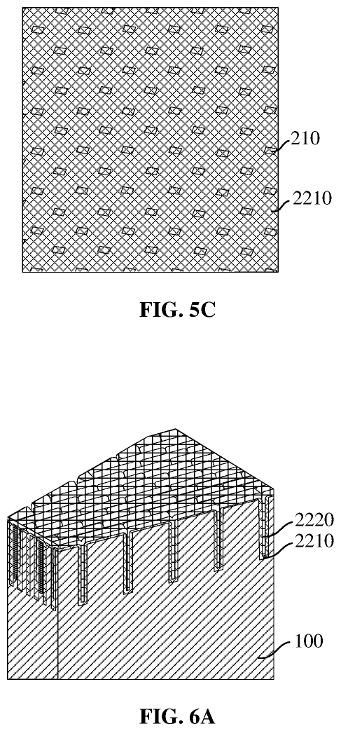

Referring to FIG. 5A to FIG. 10, in S200, an isolation structure is formed in the substrate 100. The isolation structure defines active areas 110 in the substrate 100.

Specifically, the isolation structure may include a trench 210 formed in the substrate 100, an isolation layer 220 filled in the trench 210, and a shielding layer 230 located in the isolation layer 220.

In the embodiments of the disclosure, a form of the trench 210 formed in the substrate 100 is not specifically limited. For example, the trench 210 may include a shallow trench. In this case, the isolation structure may include a shallow trench isolation structure (STI).

For example, S200 may specifically include S210 to S240, as shown in FIG. 5A to FIG. 9C. In this case, the isolation layer 220 includes a first isolation dielectric layer 221 and a second isolation dielectric layer 222.

In S210, the trench 210 is formed in the substrate 100.

In S220, the first isolation dielectric layer 221 is formed. The first isolation dielectric layer is located at a bottom and sidewalls of the trench 210.

For example, referring to FIG. 5A, FIG. 5B, and FIG. 5C, S220 may specifically include the following operation.

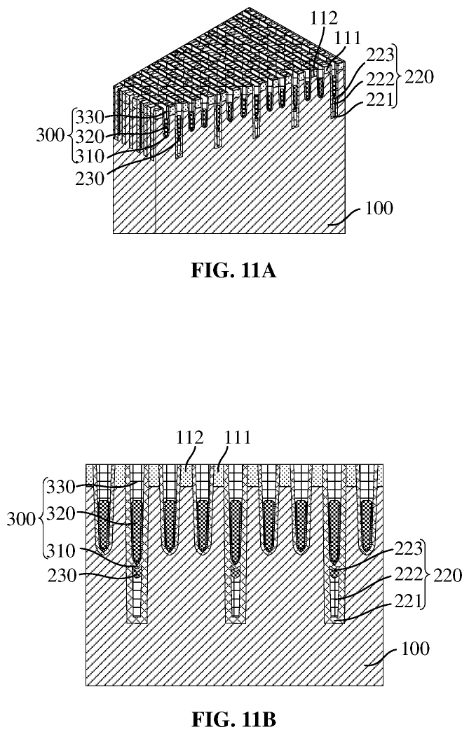

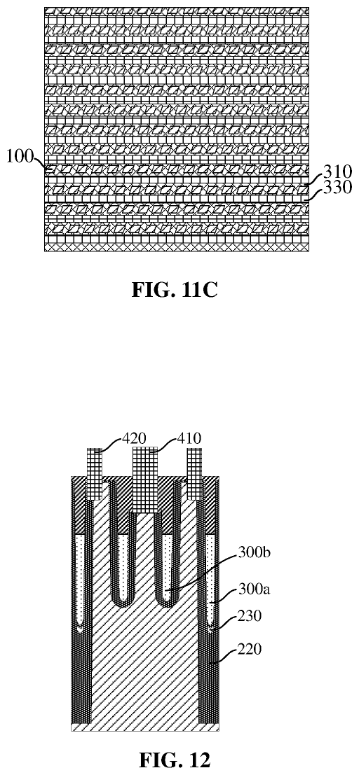

A first isolation dielectric material layer 2210 is formed. The first isolation dielectric material layer is located at a bottom and sidewalls of the trench 210 and covers an upper surface of the substrate 100. As understood in combination with FIG. 11A to FIG. 11C, during the subsequent process of forming the word line structures, the first isolation dielectric material layer 2210 covering the upper surface of the substrate 100 is removed to form the first isolation dielectric layer 221.

A material of the first isolation dielectric layer 221 is not specifically limited in the embodiments of the disclosure. For example, the first isolation dielectric layer 221 may include, but is not limited to, a first oxide layer or an oxynitride layer. A material of the first isolation dielectric material layer 2210 may be adaptively selected according to requirements of the first isolation dielectric layer 221 in an actual manufacturing process.

According to some embodiments, a material of the foregoing first oxide layer may include silicon oxide (SiO₂).

A process for forming the first isolation dielectric material layer 2210 is not specifically limited in the embodiments of the disclosure. For example, the first isolation dielectric material layer 2210 may be formed by, but not limited to, an oxide deposition process or an epitaxial growth process, and the like. According to some embodiments, the first isolation dielectric material layer 2210 may be formed by a polysilicon deposition process, a thermal oxidation process, and/or an oxide deposition process. For example, the foregoing oxide deposition process may include, but is not limited to, an atomic layer deposition (ALD for short) process.

According to some embodiments, the first isolation dielectric material layer 2210 may be formed by in-situ steam generation (ISSG). ISSG is a thermal annealing process of low pressure and rapid oxidation. ISSG can heat and cool an obtained structure in a short time, with good temperature uniformity and less thermal budget. Therefore, there are fewer defects in the first isolation medium material layer 2210 formed by ISSG, so that the product yields can be further improved. Also, the formation process requires less time, so that the production efficiency can be improved.

It is to be understood that, the operation that the first isolation dielectric material layer 2210 covering the upper surface of the substrate 100 is removed to form the first isolation dielectric layer 221, may be performed simultaneously in a subsequent process of forming word line structures 300, or may be performed before the operation of forming the word line structures 300.

Also, a process for removing the first isolation dielectric material layer 2210 covering the upper surface of the substrate 100 is not specifically limited in the embodiments of the disclosure. For example, the first insulating dielectric material layer 2210 covering the upper surface of the substrate 100 may be removed by, but is not limited to, a chemical mechanical polishing (CMP) process.

In S230, a second isolation dielectric layer 222 is formed on a surface of the first isolation dielectric layer 221. A surface of the obtained second isolation dielectric layer 222 is lower than a surface of the substrate 100 from which the trench 210 is formed.

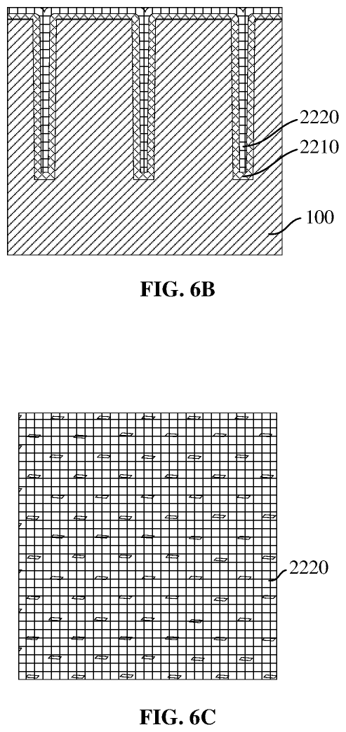

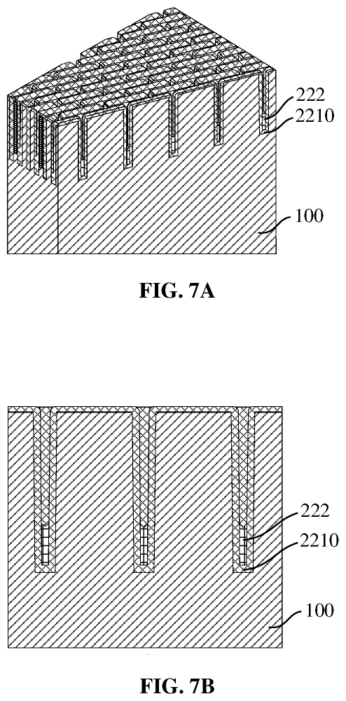

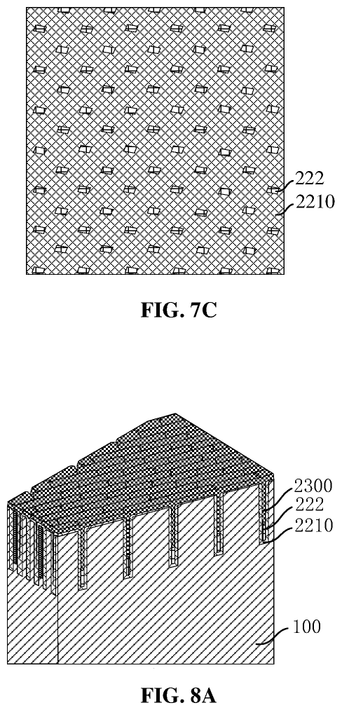

For example, referring to FIG. 6A to FIG. 6C and FIG. 7A to FIG. 7C, S230 may specifically include the following operations.

A second isolation dielectric material layer 2220 is formed. The second isolation dielectric material layer 2220 fills the trench 210 and covers a surface of the first isolation dielectric material layer 2210. The second isolation dielectric material layer 2220 located outside the trench 210 is removed. The second isolation dielectric material layer 2220 located inside the trench 210 is etched back to obtain the second isolation dielectric layer 222.

It is to be understood that, in an embodiment of the disclosure, the surface of the substrate 100 from which the trench 210 is formed may be the upper surface of the substrate 100, as shown in FIG. 4A to FIG. 5C.

A material of the second isolation dielectric layer 222 is not specifically limited in the embodiments of the disclosure. For example, the second isolation dielectric layer 222 may include, but is not limited to, a nitride layer. A material of the second isolation dielectric material layer 2220 may be adaptively selected according to requirements of the second isolation dielectric layer 222 in an actual manufacturing process.

According to some embodiments, the second isolation dielectric layer 222 may include a silicon nitride (SiN) layer.

Also, the operation that the second isolation dielectric material layer 2220 located outside the trench 210 is removed is not specifically limited in the embodiments of the disclosure. For example, the second isolation dielectric material layer 2220 located outside the trench 210 may be removed by, but is not limited to, a chemical mechanical polishing process.

In S240, a shielding layer 230 is formed on a surface of the second isolation dielectric layer 222. An upper surface of the shielding layer 230 is lower than the surface of the substrate 100 from which the trench 210 is formed.

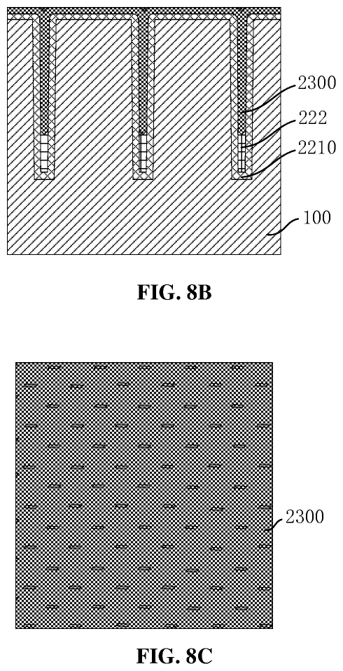

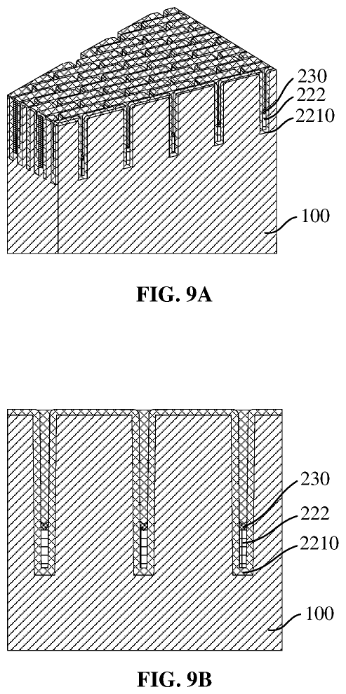

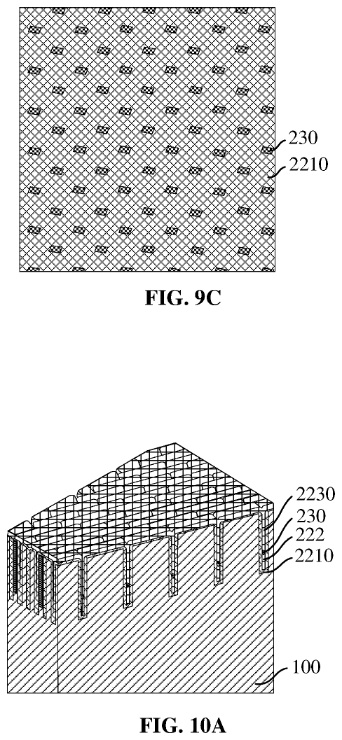

For example, referring to FIG. 8A to FIG. 8C and FIG. 9A to FIG. 9C, S240 may specifically include the following operations.

A shielding material layer 2300 is formed. The shielding material layer 2300 fills the trench 210 and covers an exposed upper surface of the first isolation dielectric material layer 2210, the shielding material layer 2300 located outside the trench 210 is removed and the shielding material layer 2300 located inside the trench 210 is etched back to form the shielding layer 230.

In the embodiments of the disclosure, a material of the shielding layer 230 is not specifically limited. For example, the shielding layer 230 includes, but is not limited to, a metal layer. In some embodiments, a material of the shielding layer 230 may be the same as a material of the word line conductive layer in the word line structure.

It is to be understood that, a material of the shielding material layer 2300 may be adaptively selected according to requirements of the shielding layer 230 in an actual manufacturing process.

According to some embodiments, the shielding layer 230 may include a tungsten (W) layer.

Also, the operation that the shielding material layer 2300 located outside the trench 210 is removed is not specifically limited in the embodiments of the disclosure. For example, the shielding material layer 2300 located outside the trench 210 may be removed by, but is not limited to, a chemical mechanical polishing process.

Referring to FIG. 11A to FIG. 11C, in S300, word line structures 300 are formed in the substrate 100.

The word line structures 300 pass through the isolation structure and the active areas and are located above the shielding layer 230.

For example, S300 may specifically include operations S310 to S330.

In S310, word line trenches are formed in the substrate 100.

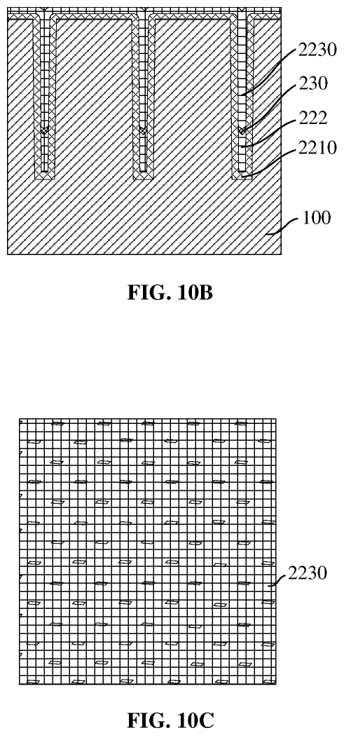

According to some embodiments, after a shielding layer is formed in S240, the method may further include an operation of forming a third isolation dielectric material layer. As understood in combination with FIG. 10A to FIG. 10C, the third isolation dielectric material layer 2230 fills the trench 210 and covers the exposed upper surface of the first isolation dielectric material layer 2210. The third isolation dielectric material layer 2230 located outside the trench 210 is subsequently removed, and part of the third layer of isolation dielectric material 2230 in the trench 210 in its height direction is removed during forming the word line trenches in S310, to form the third isolation dielectric layer 223 located between the shielding layer 230 and the word line trenches.

A material of the third isolation dielectric layer 223 is not specifically limited in the embodiments of the disclosure. For example, a material of the third isolation dielectric layer 223 may be the same with a material of the second isolation dielectric layer 222. A material of the third isolation dielectric material layer 2230 may be adaptively selected according to requirements of the third isolation dielectric layer 223 in an actual manufacturing process.

In the embodiments of the disclosure, a depth of the word line trenches is not specifically limited. For example, the word line trenches with a certain depth is formed such that a distance between the shielding layer 230 and bottoms of the word line structures 300 is smaller than a distance between the shielding layer 230 and a bottom of the isolation structure along a direction perpendicular to a plane on which the substrate is located. Thus, the shielding layer 230 is closer to the bottoms of the word line structures 300, which can produce a strong shielding effect on an electric field passing through and formed at the bottom of the word line, reduce the number of electrons adsorbed at the bottoms of the word line structures 300, and inhibit formation of leakage paths, thereby alleviating leakage caused by a switching process of the word line structures 300 and avoiding a reduction of product yields.

In S320, a gate dielectric layer 310 located at a bottom and sidewalls of each of the word line trenches is formed.

A process for forming the gate dielectric layer 310 is not specifically limited in the embodiments of the disclosure. For example, the gate dielectric layer 310 may be formed by the following operations.

A gate dielectric material layer is formed. The gate dielectric material layer fills the corresponding one of the word line trenches and covers the upper surface of the substrate 100. The gate dielectric material layer located outside the word line trench is removed, and the gate dielectric material layer located inside the word line trench is etched back to obtain the gate dielectric layer 310.

In S330, a word line conductive layer 320 is formed on a surface of the gate dielectric layer 310.

A process for forming the word line conductive layer 320 is not specifically limited in the embodiments of the disclosure. For example, the word line conductive layer 320 may be formed on the surface of gate dielectric layer 310 by, but not limited to, at least one of a chemical vapor deposition (CVD) process, a physical vapor deposition (PVD) process, a fluid chemical vapor deposition process, a plasma chemical vapor deposition (PCVD) process, an atomic layer deposition (ALD) process, or the like.

For example, an upper surface of the word line conductive layer 320 may be lower than a top surface of the corresponding word line trench.

According to some embodiments, S300 may also include an operation of forming a filling dielectric layer 330 after forming the word line conductive layer 320 in S330.

The filling dielectric layer 330 is located on a surface of the corresponding one of the word line conductive layers 320 and fills the corresponding one of the word line trenches.

A height of the filling dielectric layer 330 formed in the preceding operation is not specifically limited in the embodiments of the disclosure. For example, an upper surface of the filling dielectric layer 330 may be flush with the upper surface of the substrate 100.

Also, a material of the filling dielectric layer 330 is not specifically limited in the embodiments of the disclosure. For example, the filling dielectric layer 330 may include, but is not limited to, at least one of a silicon oxide layer, a silicon nitride layer, a silicon oxynitride (SiOₓN_{y}) layer, or the like.

According to some embodiments, a material of the filling dielectric layer 330 may be made of the same with of a material of the second isolation dielectric layer 222.

Referring further to FIG. 11A to FIG. 11C, a source 111 and a drain 112 may be formed in each of the active areas 110 after S300. The source 111 and the drain 112 are located at two opposite sides of the corresponding one of the word line structures 300.

For example, the source 111 and the drain 112 may be formed on the opposite sides of each of the word line structures 300 by ion implantation of active areas 110. A type of implanted ions used in the ion implantation of the active area 110 is not specifically limited in the embodiments of the disclosure, and the type of the implanted ions in the foregoing ion implantation process may be adaptively selected according to actual requirements.

For example, when the substrate 100 provided by S100 includes a P-type substrate, the source 111 and the drain 112 may be formed on the opposite sides of each of the word line structures 300 by implanting N-type ions into the active areas 110. Correspondingly, when the substrate 100 provided by S100 includes an N-type substrate, the source 111 and the drain 112 may be formed on the opposite sides of each of the word line structures 300 by implanting P-type ions into the active areas 110.

P-type ions and N-type ions mentioned above are not specifically limited in the embodiments of the disclosure. For example, the P-type ions involved in the embodiments of the disclosure may include, but are not limited to, at least one of boron (B) ions, gallium (Ga) ions, Indium (In) ions, or the like. For example, the N-type ions involved in the embodiments of the disclosure may include, but are not limited to, at least one of phosphorus (P) ions, arsenic (As) ions, or antimony (Sb) ions.

It is to be understood that although the operations in the flowcharts of FIG. 1 to FIG. 3 are shown sequentially as indicated by the arrows, these operations are not necessarily performed sequentially in the orders indicated by the arrows. Unless explicitly stated in the disclosure, there are no strict sequential restrictions on the execution of the operations, and the operations may be performed in other sequences. Further, at least part of the operations in FIG. 1 to FIG. 3 may include multiple operations or multiple stages. The operations or stages are not necessarily executed at the same time, but may be executed at different times. An execution sequence of these operations or stages is not necessarily sequentially, but may be executed in turn or alternately with other operations or at least part of the operations or stages in other steps.

In view of this, the embodiments of the disclosure further provide a semiconductor structure.

Referring further to FIG. 11A to FIG. 11C, the semiconductor structure includes a substrate 100 and word line structures 300 according to some embodiments.

An isolation structure is formed in substrate 100. The isolation structure defines active areas 110 in the substrate 100. The isolation structure may include a trench 210 formed in the substrate 100, an isolation layer 220 filled in the trench, and a shielding layer 230 located in the isolation layer 220. The word line structures 300 in the substrate 100 passes through the isolation structure and the active areas and are located above the shielding layer 230.

In the semiconductor structure provided by the foregoing embodiments, a shielding layer 230 that is floating is provided at bottoms of word line structures 300. The shielding layer 230 can shield an electric field to be formed at the bottom of the word line structure 300, reduce the number of electrons adsorbed at the bottom of the word line structure 300, and inhibit formation of leakage paths, thereby alleviating leakage caused by a switching process of the word line structure 300 and avoiding a reduction of product yields.

As shown in FIG. 11A to FIG. 11C, in the embodiments of the disclosure, the shielding layer 230 is located in the isolation layer 220, so the shielding layer 230 thus is located in the isolation structure. Therefore, when the word line structures 300 pass through the isolation structure and the active areas 110, the shielding layer 230 shields an electric field formed at a bottom of the word line structure 300 passing through the isolation structure (i.e., a word line structure 300 passing through an area between two adjacent active areas 110 (also called a passing word line). Meanwhile, the shielding layer has little influence on a potential near the word line structure passing through the active areas (also called a main word line), so it has little influence on the performance of the obtained device itself.

FIG. 12 shows a passing word line 300a passing through the area between the two adjacent active areas 110 and a main word line 300b passing through the active areas 110. In the semiconductor structure provided by the foregoing embodiments, when the passing word line 300a is turned on, since the shielding layer 230 can inhibit the adsorption of electrons on the surfaces of the isolation structure and the substrate 100, a leakage path from a bit line contact structure to the bottom end of the passing word line 300a and then to a node contact is avoided. Therefore, when a word line is turned on, it will not lead to leakage caused by passing through active areas and will not affect other nearby memory cells. Even if a WL address is continuously accessed for a long time, it will not lead to the loss of the information of the memory cells near the WL, which will improve product yields.

Referring further to FIG. 11A, FIG. 11B, and FIG. 11C, according to some embodiments, a distance between the shielding layer 230 and bottoms of the word line structures 300 is smaller than a distance between the shielding layer 230 and a bottom of the isolation structure along a direction perpendicular to a plane on which the substrate 100 is located.

In the semiconductor structure provided by the foregoing embodiments, the shielding layer 230 is closer to the bottoms of the word line structures 300, which can produce a strong shielding effect on an electric field passing through and formed at the bottom of the word line, reduce the number of electrons adsorbed at the bottom of the word line structure 300, and inhibit formation of leakage paths, thereby alleviating leakage caused by a switching process of the word line structure 300 and avoiding a reduction of product yields.

Referring further to FIG. 11A to FIG. 11C, the isolation layer 220 includes a first isolation dielectric layer 221 and a second isolation dielectric layer 222 according to some embodiments.

The first isolation dielectric layer 221 is located at a bottom and sidewalls of the trench 210. The second isolation dielectric layer 222 is located on a surface of the first isolation dielectric layer 221 and under the shielding layer 230.

Referring further to of FIG. 11A to FIG. 11C, the isolation layer 220 may further include a third isolation dielectric layer 223 according to some embodiments.

The third isolation dielectric layer 223 is located in the trench 210 and between the shielding layer 230 and the word line structures 300.

Referring further to FIG. 11A, FIG. 11B, and FIG. 11C, word line trenches are formed in the substrate 100, and a word line structure 300 is located in each of the word line trenches according to some embodiments.

For example, the word line structure 300 includes a gate dielectric layer 310 and a word line conductive layer 320.

The gate dielectric layer 310 is located at a bottom and sidewalls of each of the word line trenches, and the word line conductive layer 320 is located on a surface of the gate dielectric layer 310.

A material of the gate dielectric layer 310 is not specifically limited in the embodiments of the disclosure. According to some embodiments, the gate dielectric layer 310 may include a second oxide layer. In this case, the word line conductive layer 320 may include a polysilicon conductive layer.

A material of the forgoing second oxide layer is not specifically limited in the embodiments of the disclosure. For example, a material of the second oxide layer may be the same with a material of the first oxide layer.

According to some embodiments, both the material of the first oxide layer and the material of the second oxide layer may include silicon oxide.

In another embodiment, the gate dielectric layer 310 may include a high K dielectric layer that may include, but is not limited to, a hafnium oxide (HfO) layer, a zirconium oxide (ZrO₂) layer, a silicon hafnium oxide layer, an alumina (Al₂O₃) layer, or the like. In this case, the word line conductive layer 320 may include oat least one of an aluminum (Al) layer, a copper (Cu) layer, a silver (Ag) layer, a gold (Au) layer, a platinum (Pt) layer, a nickel (Ni) layer, a titanium (Ti) layer, a titanium nitride (TiN) layer, a tantalum nitride (TaN) layer, a tantalum (Ta) layer, a tantalum carbide (TaC) layer, a tantalum silicon nitride (TaSiN) layer, a tungsten nitride (WN) layer, or a tungsten silicide (WSi₂) layer.

According to some embodiments, the word line conductive layer 320 includes a tungsten layer.

According to some embodiments, both the word line conductive layer 320 and the shielding layer 230 include a tungsten layer.

Referring further to FIG. 11A to FIG. 11C, an upper surface of the word line conductive layer 320 is lower than a top surface of the corresponding word line trench according to some embodiments.

For example, each of the word line structures 300 may further include a filling dielectric layer 330.

The filling dielectric layer 330 is located on a surface of the corresponding one of the word line conductive layers 320 and fills the corresponding one of the word line trenches.

In some embodiments, an upper surface of the filling dielectric layer 330 may be flush with the upper surface of the substrate 100.

Referring further to FIG. 11A to FIG. 11C, the semiconductor structure may further include a source 111 and drain 112 in each of the active area 110 according to some embodiments.

The source 111 is located at one side of the corresponding word line structure 300. The drain 112 is located in the same active area 110 as the source 111, and the drain 112 is located at a side of the corresponding word line structure 300 far away from the source 111.

It should be noted that the method for manufacturing the semiconductor structure in the embodiments of the present disclosure can be used to manufacture the corresponding semiconductor structure. Therefore, the technical features between the method embodiments and the structural embodiments can be replaced and supplemented with each other without conflict, so that technicians in the art can learn the technical contents of the present disclosure.

According to some embodiments of the disclosure, a memory structure is provided, including the semiconductor structure provided by any of the foregoing embodiments.

The memory structure provided by the embodiments of the disclosure includes the semiconductor structure provided by any of the foregoing embodiments, so that the memory structure can also achieve the technical effects achieved by the semiconductor structure, which are not repeated here.

Referring further to FIG. 11A to FIG. 11C, in the memory structure provided by the foregoing embodiments, a shielding layer 230 that is floating is provided at bottoms of word line structures 300. The shielding layer 230 can shield an electric field to be formed at the bottom of the word line structure 300, reduce the number of electrons adsorbed at the bottom of the word line structure 300, and inhibit formation of leakage paths, thereby alleviating leakage caused by a switching process of the word line structure 300 and avoiding a reduction of product yields.

In some embodiments, the memory structure may include a core region and a periphery region located outside the core region. It is to be noted that, a semiconductor structure involved in the embodiments of the disclosure may be located in the core region of the memory structure.

For example, in the semiconductor structure in the embodiments of the disclosure, each of the word line structures may be, but is not limited to, buried word lines provided by the core region of the memory structure.

Various embodiments in the specification are described in a progressive way, and each embodiment focuses on the differences from other embodiments. For the same and similar parts between the embodiments, reference can be made to each other.

The foregoing technical features of the embodiments can be arbitrarily combined. For the sake of concise description, all possible combinations of the above-mentioned technical features of the embodiments have not been described. However, as long as there is no contradiction in the combinations of these technical features, they should be considered to be within the scope described in this specification.

The above-mentioned embodiments only represent several embodiments of the present disclosure, and the description thereof is relatively specific and detailed, but is not to be construed as limiting the scope of the patent application. It should be noted that for those skilled in the art, without departing from the concept of the present disclosure, a number of modifications and improvements may be made, which all fall within the scope of protection of the present disclosure. Therefore, the scope of protection of the patent disclosure shall be subject to the attached claims.

1. A semiconductor structure, comprising a substrate and word line structures;
wherein an isolation structure is formed in the substrate, and the isolation structure defines active areas in the substrate;
wherein the isolation structure comprises a trench formed in the substrate, an isolation layer filled in the trench, and a shielding layer located in the isolation layer; and
wherein the word line structures are located in the substrate, pass through the isolation structure and the active area alternately, and are located above the shielding layer.

2. The semiconductor structure of claim 1, wherein a distance between the shielding layer and bottoms of the word line structures is smaller than a distance between the shielding layer and a bottom of the isolation structure along a direction perpendicular to a plane on which the substrate is located.

3. The semiconductor structure of claim 2, wherein the isolation layer comprises:
a first isolation dielectric layer located at a bottom and sidewalls of the trench; and
a second isolation dielectric layer located on a surface of the first isolation dielectric layer and under the shielding layer.

4. The semiconductor structure of claim 3, wherein the isolation layer further comprises:
a third isolation dielectric layer located in the trench and between the shielding layer and the word line structures.

5. The semiconductor structure of claim 1, wherein word line trenches are formed in the substrate, and a word line structure is located in each of the word line trenches; and
wherein the word line structure comprises:
a gate dielectric layer located at a bottom and sidewalls of a word line trench; and
a word line conductive layer located on a surface of the gate dielectric layer.

6. The semiconductor structure of claim 5, wherein an upper surface of the word line conductive layer is lower than a top surface of the word line trench, and the word line structure further comprises:
a filling dielectric layer located on a surface of the word line conductive layer and filling the word line trench.

7. The semiconductor structure of claim 1, wherein each of the active areas further comprises:
a source, the source being located at one side of the corresponding one of the a word line structure passing through a corresponding active area; and
a drain, the drain being located at a side of the word line structure passing through the corresponding active area away from the source.

8. A method for manufacturing a semiconductor structure, comprising:
providing a substrate;
forming an isolation structure in the substrate, wherein the isolation structure defines active areas in the substrate, and the isolation structure comprises a trench formed in the substrate, an isolation layer filled in the trench, and a shielding layer located in the isolation layer; and
forming word line structures in the substrate, wherein the word line structures pass through the isolation structure and the active areas and are located above the shielding layer.

9. The method for manufacturing a semiconductor structure of claim 8, wherein the forming word line structures in the substrate comprises:
forming word line trenches in the substrate;
forming a gate dielectric layer at a bottom and sidewalls of each of the word line trenches; and
forming a word line conductive layer on a surface of the gate dielectric layer.

10. The method for manufacturing a semiconductor structure of claim 9, wherein the forming an isolation structure in the substrate comprises:
forming the trench, the trench being located in the substrate;
forming a first isolation dielectric layer, the first isolation dielectric layer being located at a bottom and sidewalls of the trench; and
forming a second isolation dielectric layer, the second isolation dielectric layer being located on a surface of the first isolation dielectric layer, and an upper surface of the second isolation dielectric layer being lower than a surface of the substrate from which the trench is formed; and
forming the shielding layer on a surface of the second isolation dielectric layer, an upper surface of the shielding layer being lower than the surface of the substrate from which the trench is formed.

11. The method for manufacturing a semiconductor structure of claim 10,
wherein the forming a first isolation dielectric layer comprises:
forming a first isolation dielectric material layer, the first isolation dielectric material layer being located at a bottom and sidewalls of the trench and covering an upper surface of the substrate,
wherein the forming a second isolation dielectric layer comprises:
forming a second isolation dielectric material layer, the second isolation dielectric material layer filling the trench and covering a surface of the first isolation dielectric material layer; and
removing the second isolation dielectric material layer located outside the trench, and etching back the second isolation dielectric material layer located inside the trench to form the second isolation dielectric layer,
wherein the forming the shielding layer on a surface of the second isolation dielectric layer comprises:
forming a shielding material layer, the shielding material layer filling the trench and covering an exposed upper surface of the first isolation dielectric material layer; and
removing the shielding material layer located outside the trench, and etching back the shielding material layer located inside the trench to form the shielding layer, and
wherein during forming the word line structures, the forming a first isolation dielectric layer further comprises:
removing the first isolation dielectric material layer covering the upper surface of the substrate to form the first isolation dielectric layer.

12. The method for manufacturing a semiconductor structure of claim 11, further comprising: after the forming the shielding layer on a surface of the second isolation dielectric layer,
forming a third isolation dielectric material layer, the third isolation dielectric material layer filling the trench and covering the exposed upper surface of the first isolation dielectric material layer; and
removing the third isolation dielectric material layer located outside the trench, and removing part of the third layer of isolation dielectric material in the trench in its height direction during forming the word line trenches to form a third isolation dielectric layer located between the shielding layer and the word line trenches.

13. The method for manufacturing a semiconductor structure of claim 9, wherein an upper surface of the word line conductive layer is lower than a top surface of a word line trench; and
wherein the forming word line structures in the substrate, after forming the word line conductive layer, further comprises:
forming a filling dielectric layer, the filling dielectric layer being located on a surface of the word line conductive layer and filling the word line trench.

14. The method for manufacturing a semiconductor structure of claim 8, further comprising: after the forming word line structures in the substrate,
forming a source and a drain in each of the active areas, the source and the drain being located at two opposite sides of a corresponding word line structure.

15. A memory structure, comprising the semiconductor structure of claim 1.
